(19) United States
(12) Patent Application Publication
(10) Pub. No.: US 2007/0069359 A1
(43) Pub. Date: Mar. 29, 2007

(54) Plasma display panel and the method of manufacturing the same

(76) Inventor: Tae-Joung Kweon, Suwon-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/526,130

(22) Filed: Sep. 22, 2006

(30) Foreign Application Priority Data
Sep. 27, 2005 (KR) 10-2005-0089677

(51) Int. Cl. H01L 23/24

(52) U.S. Cl. 257/687

(57) ABSTRACT

Provided are a plasma display panel and a method of manufacturing the same. The plasma display panel includes a plurality of substrates; a plurality of discharge electrode pairs formed on an inner surface of one of the substrates; a dielectric layer burying the discharge electrode pairs; barrier ribs disposed between the substrates to define a plurality of discharge cells; red, green, and blue phosphor layer coated on inner walls of the discharge cells, wherein one of the substrate s comprises a display area where an image is displayed and a non-display area corresponding to an edge of the display area and to a region where the discharge electrode pairs are connected to external terminals, and the thickness of the dielectric layer coated in the non-display area gradually increases to a boundary region between the display area and the non-display area, after which the dielectric layer is maintained at a uniform thickness in the display area. Thus, an edge hill, which is a height difference between different areas in a dielectric layer, is removed. Accordingly, a gap between a front panel and a rear panel can be removed when the front panel and the rear panel are assembled, thereby preventing driving noise.

### CROSS-REFERENCE TO RELATED PATENT APPLICATION

This application claims the benefit of Korean Patent Application No. 10-2005-0089677, filed on Sep. 27, 2005, in the Korean Intellectual Property Office, the disclosure of which is incorporated herein in its entirety by reference.

### BACKGROUND OF THE INVENTION

1. Field of the Invention

The present embodiments relate to a plasma display panel, and more particularly, to a plasma display panel having a modified dielectric layer to prevent generating an edge hill between substrates, and a method of manufacturing the same.

2. Description of the Related Art

A plasma display panel (PDP) is a flat display device that displays images using light emitted from a phosphor material formed in a discharge space filled with a discharge gas when ultraviolet rays are generated by applying a predetermined voltage to discharge electrodes formed on each of a plurality of substrates facing each other.

When the plasma display panel is a three-electrode surface discharge type, the three-electrode surface discharge type plasma display panel includes: a front substrate; sustain electrode pairs formed on an inner surface of the front substrate; a front dielectric layer burying the sustain electrode pairs; a protection film layer formed on a surface of the front dielectric layer; a rear substrate disposed parallel to the front substrate; address electrodes which are disposed on an inner surface of the rear substrate and cross the sustain electrode pairs; a rear dielectric layer burying the address electrodes; barrier ribs disposed between the front substrate and the rear substrate; a phosphor layer coated on inner walls of the barrier ribs; and a discharge gas filled in discharge cells defined by the barrier ribs.

A process of manufacturing the plasma display panel can include a process of manufacturing a front panel, a process of manufacturing a rear panel, and a process of assembling the front and rear panels.

The process of manufacturing the front panel includes patterning a sustain electrode pair on a front substrate, printing a front dielectric layer to bury the sustain electrode pair, and depositing a protection film layer on the front dielectric layer.

The process of manufacturing the rear panel includes patterning address electrodes on a rear substrate, printing a rear dielectric layer to bury the address electrodes, forming barrier ribs on an upper surface of the rear dielectric layer using a sand blasting method, and printing a phosphor layer on the inner walls of the barrier ribs.

The process of assembling the front panel and the rear panel includes sealing the front panel and the rear panel by coating frit glass along edges of surfaces of the front panel and the rear panel facing each other, vacuuming a discharge space to remove moisture and impurities from the sealed discharge space, injecting a discharge gas into the discharge space, generating an aging discharge by applying a predetermined voltage to the assembled panel, and mounting IC (integrated circuit) chips.

However, conventional dielectric layers are formed using a printing method. That is, a screen mask is aligned on a substrate, and a material for forming the dielectric layer is loaded on the mask.

However, as depicted in FIG. 1, in a conventional printing method, when a screen mask (not shown) is separated from a substrate 110 after a dielectric layer 120 is printed on the substrate 110, a height H₂ of a portion 122 of the dielectric layer 120 on an edge of the substrate 110 is higher than a height H₁ of the dielectric layer 120.

Accordingly, a height difference g, that is, an edge hill, is generated between the portion 122 of the dielectric layer 120 on the edge of the substrate 110 and the portion 121 of the dielectric layer 120 on the inner portion of the substrate 1 10. The edge hill causes a gap when the front panel and the rear panel are assembled, that is, the front panel and the rear panel cannot be tightly contacted due to the edge hill, thereby generating noise during operation and degrading the quality of the plasma display panel.

### SUMMARY OF THE INVENTION

According to an aspect of the present embodiments, there is provided a method of manufacturing a plasma display panel, comprising: preparing a substrate; coating a dielectric raw material on a surface of the substrate using a coater; and forming a dielectric layer by firing the dielectric raw material.

The coating of the dielectric raw material may comprise coating the dielectric raw material to a gradually increasing thickness from a non-display area corresponding to an edge of the substrate to a boundary region between the non-display area and a display area, and coating the dielectric raw material uniformly in the display area.

A thickness of the dielectric layer coated in the display area may be relatively thicker than that of the dielectric layer coated in the non-display area.

According to another aspect of the present embodiments, there is provided a method of manufacturing a plasma display panel, comprising: preparing a substrate; aligning a dielectric sheet on the substrate; and forming a dielectric layer by attaching the dielectric sheet to the substrate.

The forming of the dielectric layer by attaching the dielectric sheet on the substrate may comprise attaching the dielectric sheet to the substrate while the aligned substrate and the dielectric sheet pass through a plurality of rollers mounted on both sides of the aligned substrate and the dielectric sheet to apply predetermined heat and pressure to the substrate and the dielectric sheet.

According to another aspect of the present embodiments, there is provided a plasma display panel comprising: a plurality of substrates; a plurality of discharge electrode pairs formed on an inner surface of one of the substrates; a dielectric layer burying the discharge electrode pairs; barrier ribs disposed between the substrates to define a plurality of discharge cells; red, green, and blue phosphor layer coated on inner walls of the discharge cells, wherein one of the substrates comprises a display area where an image is displayed and a non-display area corresponding to an edge of the display area and to a region where the discharge electrode pairs are connected to external terminals, and the thickness of the dielectric layer coated in the non-display area gradually increases to a boundary region between the non-display area and the display area, after which the dielectric layer is maintained in a uniform thickness in the display area.

The dielectric layer coated in the display area may be relatively greater thickness than the dielectric layer coated in the non-display area.

The dielectric layer may be formed using one of a coating method and a dielectric sheet method.

### BRIEF DESCRIPTION OF THE DRAWINGS

The above and other features and advantages of the present embodiments will become more apparent by describing in detail exemplary embodiments thereof with reference to the attached drawings in which:

FIG. 1 is a cross-sectional view of a substrate having a conventional dielectric layer;

FIG. 2 is a partial cutaway exploded perspective view of a plasma display panel according to an embodiment;

FIG. 3A is a cross-sectional view illustrating a coated material for forming a dielectric layer on a substrate according to an embodiment;

FIG. 3B is an enlarged cross-sectional view of FIG. 3A;

FIG. 4A is a cross-sectional view illustrating an attachment of a sheet for a dielectric layer to a substrate according to another embodiment; and

FIG. 4B is a cross-sectional view illustrating the attached sheet for the dielectric layer on the substrate of FIG. 4A.

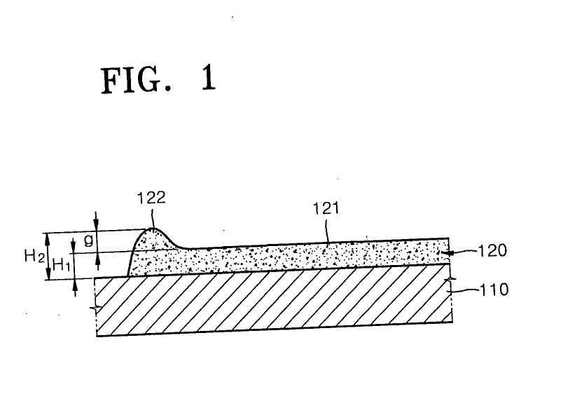

### DETAILED DESCRIPTION OF THE INVENTION

The present embodiments will now be described with reference to the accompanying drawings in which exemplary embodiments are shown.

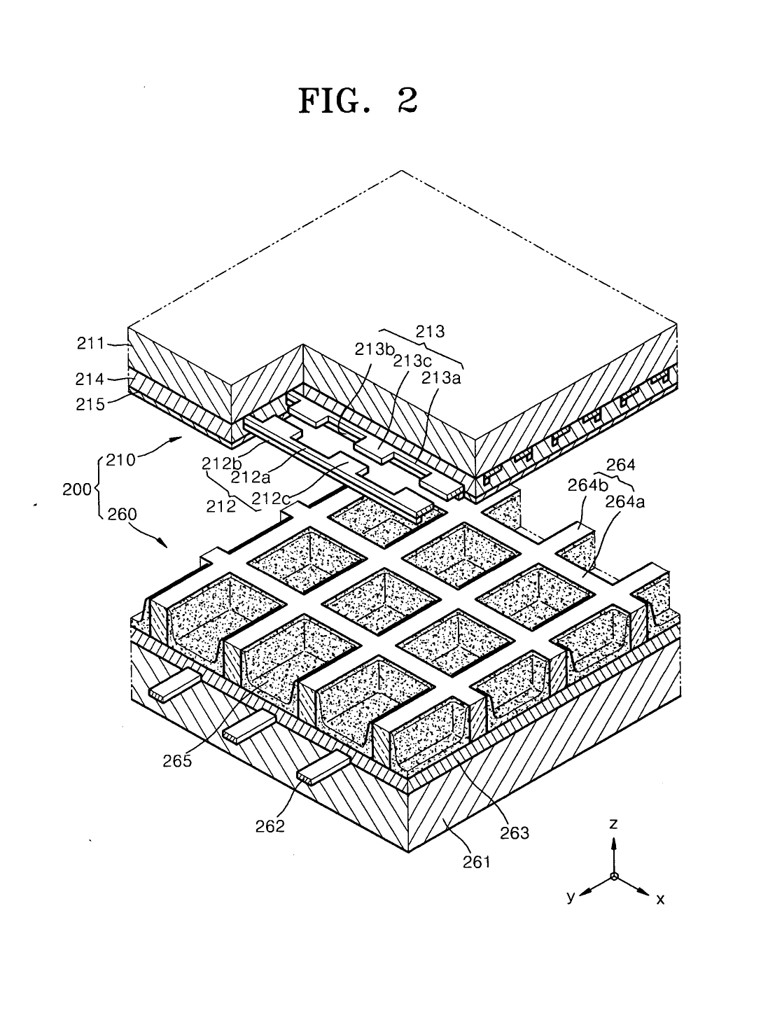

FIG. 2 is a partial cutaway exploded perspective view of a plasma display panel 200 according to an embodiment.

Referring to FIG. 2, the plasma display panel 200 includes a front panel 210 and a rear panel 260 parallel to each other. Frit glass is coated on edges of inner surfaces of the front panel 210 and the rear panel 260 to form a sealed discharge space.

The front panel 210 includes a transparent front substrate 211 formed of, for example, soda lime glass. Sustain electrode pairs, each including an X electrode 212 and a Y electrode 213, are formed on an inner surface of the front substrate 211 along an X direction of the plasma display panel 200. The X and Y electrodes 212 and 213 are alternately disposed along a Y direction of the plasma display panel 200.

The X electrode 212 includes a first transparent electrode line 212a formed on an inner surface of the front substrate 211 and a first bus electrode line 212b partially overlapping the first transparent electrode line 212a. The first bus electrode line 212b is disposed along an edge of the first transparent electrode line 212a. A first protrusion electrode 212c formed in one unit with the first transparent electrode line 212a protrudes from an inner wall of the first transparent electrode line 212a toward the Y electrode 213.

The Y electrode 213 includes a second transparent electrode line 213a and a second bus electrode line 213b partially overlapping the second transparent electrode line 213a. The second bus electrode line 213b is disposed along an edge of the second transparent electrode line 213a. A second protrusion electrode 213c formed in one unit with the second transparent electrode line 213a protrudes from an inner wall of the second transparent electrode line 213a toward the X electrode 212.

The first protrusion electrode 212c formed in one unit with the first transparent electrode line 212a and the second protrusion electrode 213c formed in one unit with the second transparent electrode line 213a are transparent conductive films, for example, an indium tin oxide (ITO) film, to increase an opening ratio of the front substrate 211. The first and second bus electrode lines 212b and 213b are formed of a highly conductive metal, for example, an Ag paste or a multiple layer structure of Cr—Cu—Cr, to reduce line resistance and to increase the electrical conductivity of the first and second transparent electrode lines 212a and 213a.

The X and Y electrodes 212 and 213 are buried in the front dielectric layer 214. The front dielectric layer 214 may be selectively formed on portions where the X and Y electrodes 212 and 213 are patterned or may be coated on the entire lower surface of the front substrate 211. The protection film layer 215, which may be formed of, for example, MgO is deposited on a surface of the front dielectric layer 214 to prevent the front dielectric layer 214 from being damaged or to increase the emission of secondary electrons.

The rear panel 260 includes a rear substrate 261. Address electrodes 262 are disposed on the rear substrate 261 crossing the X and Y electrodes 212 and 213. The address electrodes 262 can be buried in a rear dielectric layer 263.

Barrier ribs 264 that define a plurality of discharge cells in a space are formed between the front and rear panels 210 and 260. The barrier ribs 264 include first barrier ribs 264a disposed crossing the address electrodes 262 and second barrier ribs 264b disposed parallel to the address electrodes 262. The first barrier ribs 264a extend from inner walls of an adjacent second barrier ribs 264b facing each other, and the first and second barrier ribs 264a and 264b form a matrix type discharge cell when the first and second barrier ribs 264a and 264b are coupled.

The discharge cells defined by the front and rear panels 210 and 260 and the barrier ribs 264 are filled with a discharge gas such as, for example, a Ne—Xe gas or a He—Xe gas. Also, the discharge cell is coated with red, green, and blue phosphor layers 265 that emit visible light when the phosphor layers 265 are excited by ultraviolet rays generated from the discharge gas. The red, green, and blue phosphor layers 265 can be coated on any surface of the discharge cells.

A process of manufacturing the plasma display panel 200 can include a process of manufacturing a front panel 210, a process of manufacturing a rear panel 260, and a process of assembling the front and rear panels 210 and 260.

The process of manufacturing the front panel 210 includes patterning the X and Y electrodes 212 and 213 on the front substrate 211, printing the front dielectric layer 214 to bury the X and Y electrodes 212 and 213, and depositing the protection film layer 215 on the front dielectric layer 214.

The process of manufacturing a rear panel 260 includes forming address electrodes 262 on the rear substrate 261, forming the rear dielectric layer 263 to bury the address electrodes 262, forming the barrier ribs 264 to define the plurality of discharge cells in a discharge space, and coating red, green, and blue phosphor layers on the inner walls of the barrier ribs 264.

Next, frit glass is coated along edges of surfaces of the front panel 210 and the rear panel 260 facing each other to seal a discharge space therebetween. Afterward, the discharge space is vacuumed and filled with a discharge gas and an aging process is performed.

To exhaust air and impurity gases remaining in the discharge space between the front and rear panels 210 and 260 during the vacuuming process, a pipeline is formed on a side of the rear panel 260.

The front dielectric layer 214 and the rear dielectric layer 263 can be formed to have a uniform thickness using a coater, which will now be described.

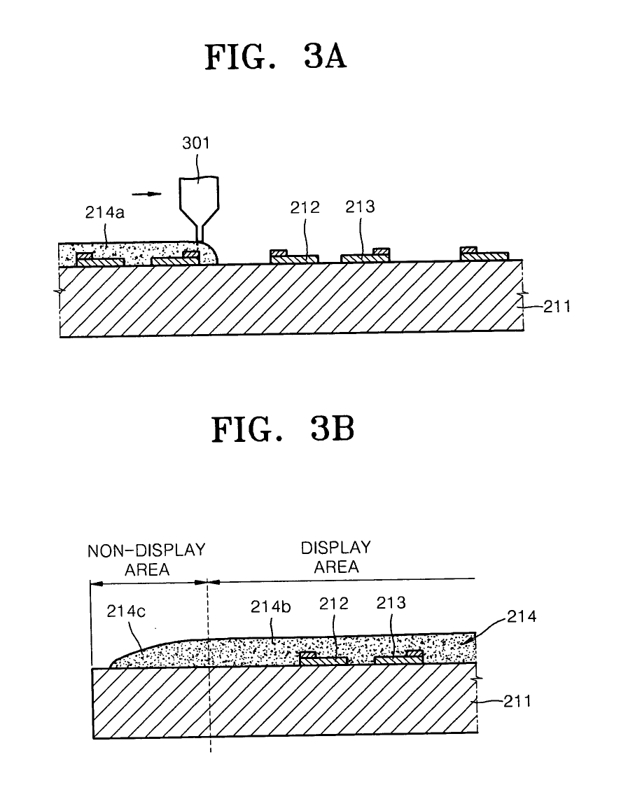

FIG. 3A is a cross-sectional view illustrating a coated material for forming a dielectric layer on a substrate according to an embodiment, and FIG. 3B is an enlarged cross-sectional view of FIG. 3A.

In the current embodiment, the front substrate 211 will be described, but the present embodiments are not limited thereto, that is, any dielectric layer that buries discharge electrodes can be applied.

Referring to FIG. 3A, after a front substrate 211 is prepared, the front substrate 211 is washed using a glass washing liquid. An X electrode 212 and a Y electrode 213 are patterned on a surface of the front substrate 211. A dielectric raw material 214a is sprayed from a nozzle unit 301 of a coater onto the front substrate 211 where the X and Y electrodes 212 and 213 are formed.

The nozzle unit 301 coats the dielectric raw material 214a to a thickness sufficient to bury the X and Y electrodes 212 and 213 while moving in a direction from one end of the substrate 211 to the other.

A front dielectric layer 214 resulting from the deposited raw material 214a has a thickness of from about 30 um to about 40 um. Therefore, the dielectric raw material 214a can be coated on the front substrate 211 in one process by applying a predetermined pressure to the nozzle unit 301. If the thickness of the dielectric layer formed by firing the dielectric raw material is less than about 30 um, there is a risk of breaking the dielectric layer due to the withstand voltage of the dielectric layer being too low. On the contrary, if the thickness of the dielectric layer formed by firing the dielectric raw material is greater than about 40 um, a firing voltage (Vf) may become high.

Referring to FIG. 3B, the front substrate 211 is divided into a display area where an image is displayed and a non-display area which corresponds to an edge portion of a display region and corresponds to a region where the X and Y electrodes 212 and 213 are connected to external terminals.

When the dielectric raw material 214a discharged from the nozzle unit 301 of the coater is hardened at a high temperature, the process of forming the front dielectric layer 214, including both the display area and the non-display area, is completed.

The thickness of a portion 214c of the front dielectric layer 214 coated in the non-display area gradually increases to a boundary region between the display area and the non-display area, and then, a portion 214b of the front dielectric layer 214 is maintained at a uniform thickness in the display area. Also, the front dielectric layer 214b is coated relatively thicker than the front dielectric layer 214c.

This is because the nozzle unit 301 starts discharging the dielectric raw material 214a in the non-display area where a relatively low amount of the dielectric raw material 214a is discharged. Afterward, the dielectric raw material 214a is maintained at a uniform thickness in the display area. At an end of the display area, i.e., at the other non-display area (not shown) opposite to the starting point, a relatively low amount of the dielectric raw material 214a is discharged.

Although it is not depicted, frit glass is coated on edges of surfaces of a plurality of panels facing each other, and at least one column shaped protrusion unit formed in one unit with the front dielectric layer is formed on the dielectric raw material 214a coated in the non-display area. Thus, the column shaped protrusion unit can be buried in the frit glass. In this configuration, the frit glass can effectively absorb noise when there is a vibration since the frit glass is formed of a different material from the protrusion unit.

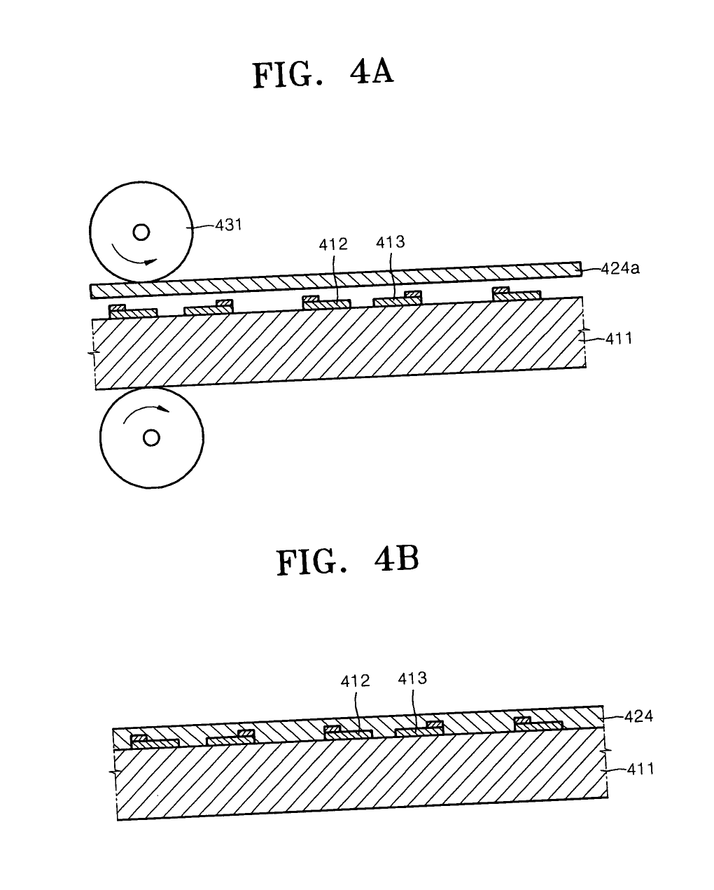

FIG. 4A is a cross-sectional view illustrating an attachment of a sheet for a dielectric layer to a substrate according to another embodiment, and FIG. 4B is a cross-sectional view illustrating the attached sheet for the dielectric layer on the substrate of FIG. 4A.

Referring to FIG. 4A, after a front substrate 411 is prepared, the front substrate 411 is washed using a glass washing liquid. An X electrode 412 and a Y electrode 413 are patterned on a surface of the washed front substrate 411. The X and Y electrodes 412 and 413 formed of a photosensitive electrode paste are printed on a surface of the front substrate 411 using a screen mask. Then, the X and Y electrodes 412 and 413 are patterned by exposing, developing, and annealing.

Afterward, a dielectric sheet 424a is aligned on the front substrate 411. The dielectric sheet 424a may be formed of a dry film resistor having high dielectricity. The dielectric sheet 424a passes through a plurality of rollers 431 which apply predetermined heat and pressure while the dielectric sheet 424a is aligned on the front substrate 411.

Accordingly, the dielectric sheet 424a is attached to a surface of the front substrate 411 and the X and Y electrodes 412 and 413 are buried thereunder. The dielectric sheet 424a is then attached to the entire region of the front substrate 411 including a display area and a non-display area. This prevents a gap from being generated between the front substrate 411 and the dielectric sheet 424a while they pass through the rollers 431 which could result in a failed product. Through the processes described above, as depicted in FIG. 4B, the manufacturing of the front dielectric layer 424 is carried out.

A plasma display panel and a method of manufacturing the plasma display panel according to the present embodiments provide the following advantages.

First, a gap can be prevented from being formed between a front panel and a rear panel by removing an edge hill, thereby preventing driving noise.

Second, a dielectric layer in a display area has a uniform thickness since the dielectric layer is formed by coating a dielectric raw material using a coater or attaching a dielectric sheet using rollers.

The present embodiments provide a plasma display panel that prevents noise by removing an edge hill and a method of manufacturing the plasma display panel.

While the present embodiments have been particularly shown and described with reference to exemplary embodiments thereof, it will be understood by those of ordinary skill in the art that various changes in form and details may be made therein without departing from the spirit and scope of the present embodiments as defined by the following claims.

What is claimed is:

1. A method of manufacturing a plasma display panel, comprising:
providing a substrate;
coating a dielectric raw material on a surface of the substrate using a coater; and
forming a dielectric layer by firing the dielectric raw material.

2. The method of claim 1, wherein the coating of the dielectric raw material comprises coating the dielectric raw material to a gradually increasing thickness from a non-display area corresponding to an edge of the substrate to a boundary region between the non-display area and a display area, and coating the dielectric raw material uniformly in the display area.

3. The method of claim 2, wherein the thickness of the dielectric layer coated in the display area is relatively thicker than that of the dielectric layer coated in the non-display area.

4. The method of claim 1, further comprising the step of patterning a plurality of discharge electrode pairs on the entire region of the substrate.

5. The method of claim 1, wherein the dielectric layer has a thickness of from about 30um to about 40um.

6. A method of manufacturing a plasma display panel, comprising:
providing a substrate;
aligning a dielectric sheet on the substrate; and
forming a dielectric layer by attaching the dielectric sheet to the substrate.

7. The method of claim 6, wherein the step of forming the dielectric layer by attaching the dielectric sheet to the substrate comprises attaching the dielectric sheet to the substrate while the aligned substrate and the dielectric sheet pass through rollers mounted on both sides of the aligned substrate and the dielectric sheet thereby applying predetermined heat and pressure to the substrate and the dielectric sheet.

8. The method of claim 6, further comprising the step of forming a plurality of discharge electrode pairs buried by the dielectric sheet on a surface of the substrate.

9. The method of claim 6, wherein the dielectric layer has a thickness of from about 30 um to about 40 um.

10. A plasma display panel comprising:
a plurality of substrates;
a plurality of discharge electrode pairs formed on an inner surface of one of the substrates;
a dielectric layer burying the discharge electrode pairs;
barrier ribs disposed between the substrates to define a plurality of discharge cells;
red, green, and blue phosphor layer coated on inner walls of the discharge cells, wherein
wherein at least one of the substrates comprises a display area where an image is displayed and a non-display area corresponding to an edge of the display area and a region where the discharge electrode pairs are connected to external terminals, and
wherein the thickness of the dielectric layer coated in the non-display area gradually increases to a boundary region between the non-display area and the display area, and
wherein the dielectric layer is maintained at a uniform thickness in the display area.

11. The plasma display panel of claim 10, wherein the dielectric layer coated in the display area is relatively thicker than the dielectric layer coated in the non-display area.

12. The plasma display panel of claim 10, wherein the dielectric layer is formed using at least one of a coating method and a dielectric sheet method.

13. The plasma display panel of claim 12, wherein the dielectric sheet is a dry film resistor.

14. The plasma display pane of claim 10, wherein the dielectric layer has a thickness of from about 30 um to about 40 um.
